(19) United States
(12) Patent Application Publication
(10) Pub. No.: US 2005/0194034 A1
(43) Pub. Date: Sep. 8, 2005

(54) Thermoelectric generator

(76) Inventors: Hiroo Yamaguchi, Toyohashi-city (JP); Yasutoshi Yamanaka, Kariya-city (JP); Hiroya Inaoka, Toyota-city (JP); Rentaro Mori, Kasugai-city (JP)

Correspondence Address: HARNESS, DICKEY & PIERCE, P.L.C., P.O. BOX 828, BLOOMFIELD HILLS, MI, 48303, US

(21) Appl. No.: 11/070,798

(22) Filed: Mar. 2, 2005

(30) Foreign Application Priority Data
Mar. 4, 2004 (JP) 2004-061383

(51) Int. Cl. H01L 35/30

(52) U.S. Cl. 136/205

(57) ABSTRACT

A thermoelectric generator has a plurality of hot-side heat source portions, a plurality of cold-side heat source portions, a thermoelectric element, a hot-side communicator and a cold-side communicator. Hot fluid flows in the plurality of hot-side heat source portions, and cold fluid colder than the hot fluid flows in the plurality of cold-side heat source portions. The heat source portions are alternately stacked in such a manner of interposing the thermoelectric element between the hot-side heat source portion and the cold-side heat source portion. The hot-side communicator communicates the hot-side heat source portions, and the cold-side communicator communicates the plurality of cold-side heat source portions. Each of the hot-side communicator and the cold-side communicator has a distance adjuster for adjusting distances between the hot-side heat source portions and the cold-side heat source portions so as to bring them in contact with the thermoelectric elements in the stacking direction thereof.

### CROSS REFERENCE TO RELATED APPLICATION

This application is based upon and claims the benefit of priority of Japanese Patent Application No. 2004-061383 filed on Mar. 4, 2004, the content of which is incorporated herein by reference.

### FIELD OF THE INVENTION

The present invention relates to a thermoelectric generator that generates an electric power by Seebeck effect applying a temperature difference to a thermoelectric element.

### BACKGROUND OF THE INVENTION

JP-10-136672-A discloses a conventional thermoelectric generator having a plurality of heat exchangers for heating and for cooling alternately stacked and thermoelectric generation modules disposed between the heat exchangers. The heat exchangers are communicated to each other by an emission gas supply pipe at one end side thereof and by an emission gas emission pipe at another end side thereof so that the emission gas flows through all of the heat exchangers. Specifically, each of the emission gas supply pipe and the emission gas emission pipe has a plurality of branch pipes toward the plurality of the heat exchanger for heating. A branch pipe of the emission gas supply pipe and that of the emission gas emission pipe are connected to and integrally formed with each of the heat exchanger for heating.

The heat exchanger for cooling has a structure similar to that of the above description. The heat exchangers are communicated to each other by branch pipes of a cooling water supply pipe and by branch pipes of a cooling water emission pipe so that cooling water flows through all of the heat exchangers.

To reduce a thermal transfer resistance caused by surface asperities (surface roughness) of the heat exchangers in contact with the thermoelectric generation modules, helium gas is filled between the thermoelectric generation modules and the heat exchangers. Further, to apply a uniform pressure to the heat exchangers for heating, the thermoelectric generation modules and the heat exchangers for cooling in a stack, a pressurizing means (a bellows) is provided for pressurizing a fluid media (air, nitrogen, silicon oil, etc.).

However, in the above conventional art, the thermoelectric generator has an extremely complicated configuration as a whole, by filling helium gas and by setting the pressurizing means (the bellows). Especially, each of the heat exchangers are integrally connected by a plurality of branch pipes of the supply pipes and the emission pipes, making the clearances between the heat exchangers vary, and leading the pressurizing means to a complicated configuration for assembling the heat exchangers and the thermoelectric generation modules in secure contact with each other, predicated on deforming them.

### SUMMARY OF THE INVENTION

The object of the present invention, in view of the above issues, is to provide a thermoelectric generator having multi-layer capable of bringing thermoelectric elements, hot-side heat source portion and cold-side heat source portion in well contact with each other, without heavy configurations.

To achieve the above object, a thermoelectric generator according to the present invention comprises a plurality of hot-side heat source portions, a plurality of cold-side heat source portions, a thermoelectric element, a hot-side communicator and a cold-side communicator. Hot fluid flows in the plurality of hot-side heat source portions, and cold fluid colder than the hot fluid flows in the plurality of cold-side heat source portions. The hot-side heat source portions and the cold-side heat source portions are alternately stacked in such a manner of interposing the thermoelectric element between the hot-side heat source portion and the cold-side heat source portion. The hot-side communicator communicates the plurality of hot-side heat source portions, and the cold-side communicator communicates the plurality of cold-side heat source portions. Each of the hot-side communicator and the cold-side communicator has a distance adjuster for adjusting distances between the hot-side heat source portions and the cold-side heat source portions so as to bring them in contact with the thermoelectric elements in the stacking direction thereof.

### BRIEF DESCRIPTION OF THE DRAWINGS

Other features and advantages of the present invention will be appreciated, as well as methods of operation and the function of the related parts, from a study of the following detailed description, the appended claims, and the drawings, all of which form a part of this application. In the drawings:

FIG. 1 is a schematic diagram showing an entire structure including an engine according to a first embodiment of the present invention;

FIG. 2 is a front view showing an exterior appearance of a thermoelectric generator in FIG. 1;

FIG. 3 is a plan view showing an exterior appearance of a thermoelectric generator in FIG. 1;

FIG. 4A is a plan view showing a high temperature side heat source portion (for an uppermost layer);

FIG. 4B is a front view showing a high temperature side heat source portion (for an uppermost layer);

FIG. 5A is a plan view showing a high temperature side heat source portion (for a general layer);

FIG. 5B is a front view showing a high temperature side heat source portion (for a general layer);

FIG. 6A is a plan view showing a low temperature side heat source portion (for an uppermost layer);

FIG. 6B is a front view showing a low temperature side heat source portion (for an uppermost layer);

FIG. 7A is a plan view showing a low temperature side heat source portion (for a general layer);

FIG. 7B is a front view showing a low temperature side heat source portion (for a general layer);

FIG. 8 is an exploded diagram showing an assembling way of the high temperature side heat source portions, the low temperature side heat source portions and thermoelectric elements;

FIG. 9 is a front vertical-sectional view showing an exterior appearance of a thermoelectric generator according to a second embodiment;

FIG. 10 is an exploded vertical-sectional diagram showing an assembling way of the high temperature side heat source portions and the low temperature side heat source portions in FIG. 9;

FIG. 11 is a front view showing an exterior appearance of a thermoelectric generator according to a third embodiment;

FIG. 12 is a schematic diagram showing an entire structure including an engine according to a first other embodiment;

FIG. 13 is a schematic diagram showing an entire structure including an engine according to a second other embodiment; and

FIG. 14 is a schematic diagram showing an entire structure including an engine according to a third other embodiment.

### DESCRIPTION OF THE PREFERRED EMBODIMENTS

### First Embodiment

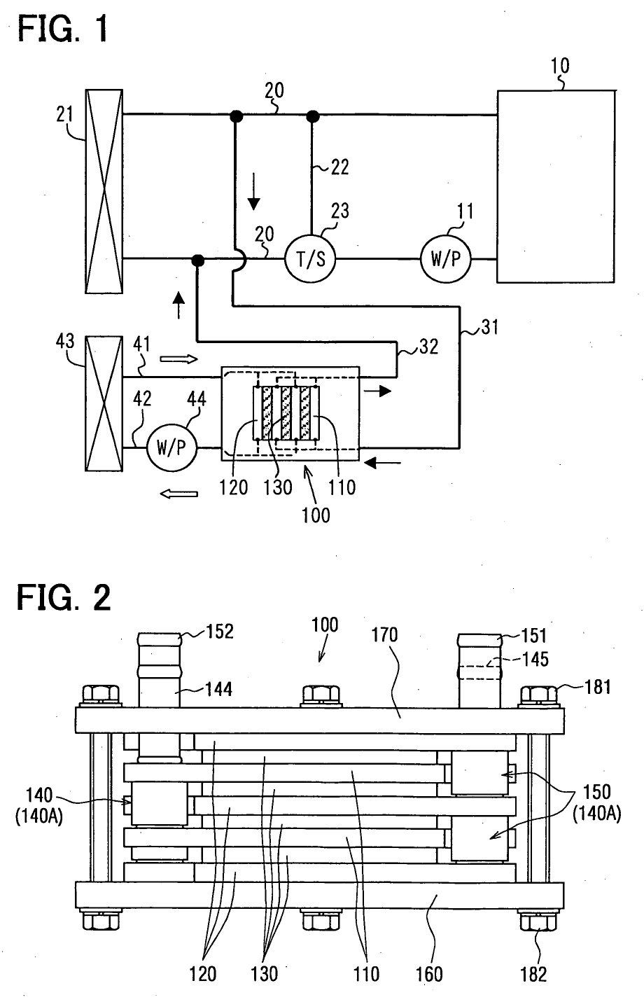

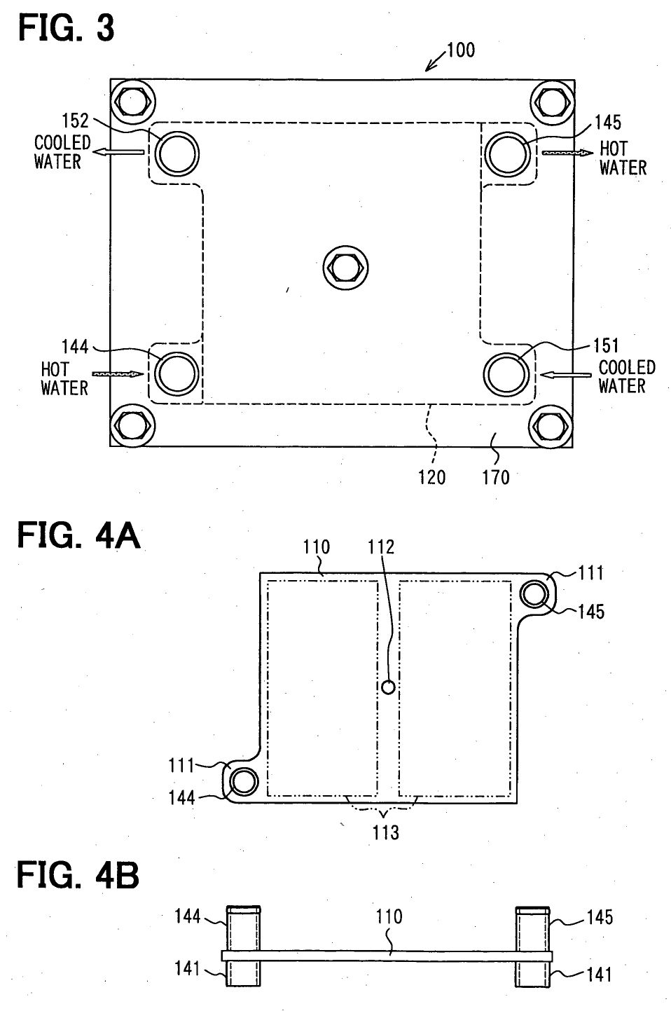

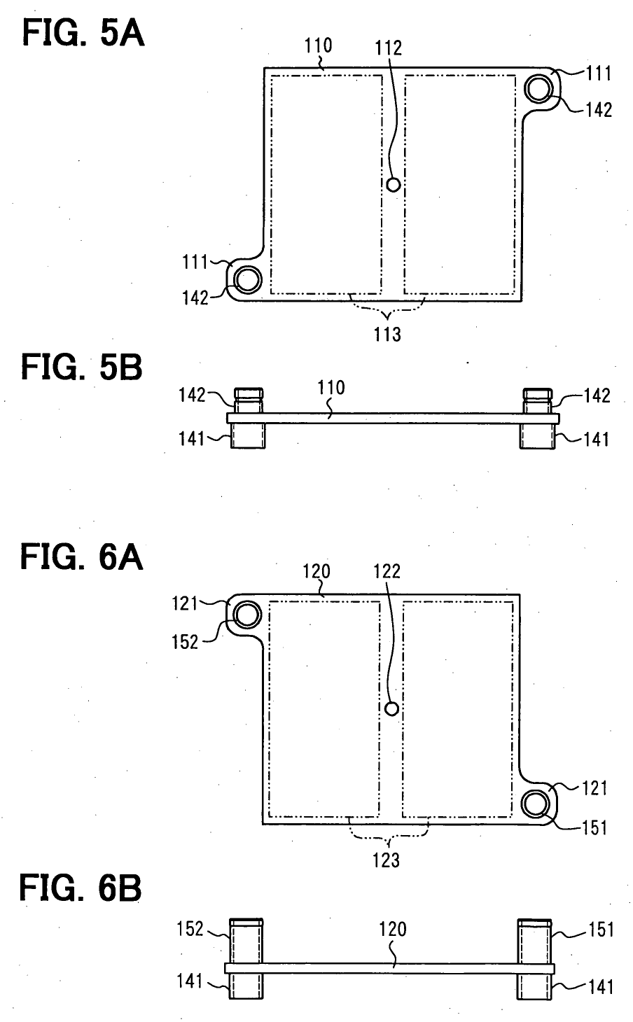

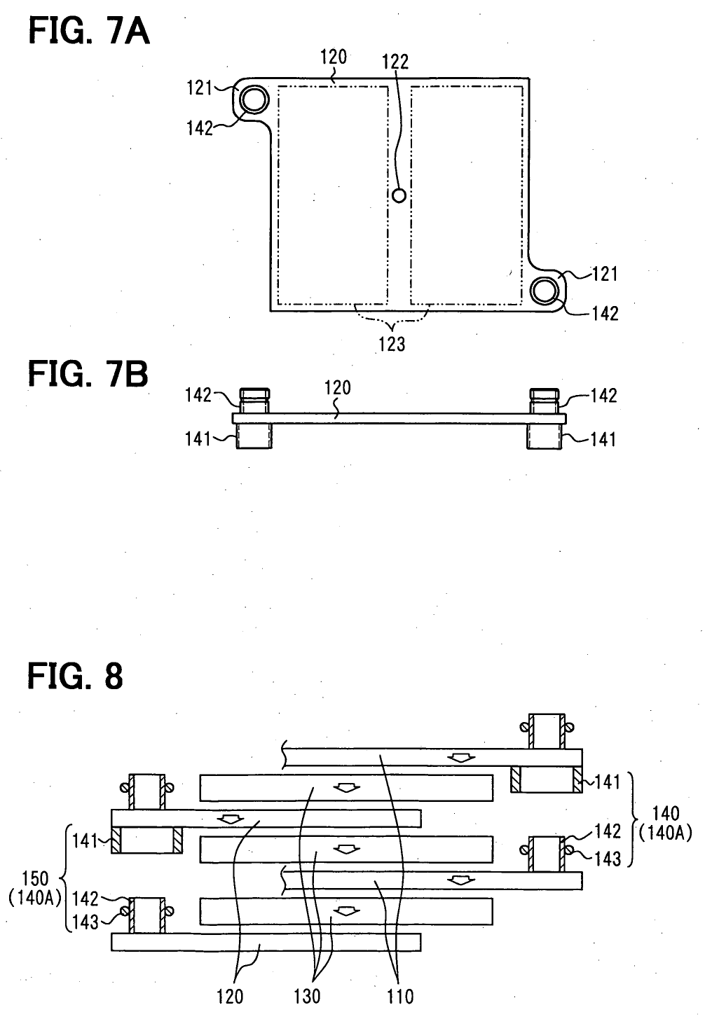

A thermoelectric generator 100 according to the present invention is applied to a vehicle having a water-cooled engine 10, wherein an electric energy is recovered from a discharged heat energy associated with a cooling of the engine 10. First, a fundamental structure thereof will be described with reference to FIGS. 1 to 8. Here, FIG. 1 is a schematic diagram showing an entire structure including the engine 10. FIGS. 2 and 3 are a front view and a plan view showing an exterior appearance of a thermoelectric generator 100. FIGS. 4 and 5 are plan views and front views showing a high temperature side heat source portions 110. FIGS. 6 and 7 are plan views and front views showing a low temperature side heat source portions 120. FIG. 8 is an exploded diagram showing an assembling way of the high temperature side heat source portions 110, the low temperature side heat source portions 120 and thermoelectric elements 130.

As shown in FIG. 1, the engine 10 has an engine coolant circuit 20 and a radiator 21. A water pump 11 circulates coolant in the engine 10 through the engine coolant circuit 20 and the radiator 21. Here, the water pump 11 is an engine driven type pump run by the driving force of the engine 10. A heat radiation by the radiator 21 cools the coolant so as to control the operation temperature of the engine 10 adequately. Incidentally, the engine coolant circuit 20 has a bypass 22 for detouring the coolant around the radiator 21 and a thermostat (a flow amount control valve) 23 for adjusting a flow amount of the coolant flowing through the bypass 22. When the temperature of the coolant is not over a predetermined value (for example, 90° C.), the thermostat 23 shuts a flow of the coolant through the radiator 21 so as to flow the coolant through the bypass 22 to prevent the coolant from being excessively cooled.

The engine coolant circuit 20 has a hot coolant inflow pipe 31 that branches at a node between a point upstream of the radiator 20 and the bypass 22, and a hot coolant outflow pipe 32 that branches at a node between a point downstream of the radiator 21 and the thermostat 23. The hot coolant inflow pipe 31 and the hot coolant outflow pipe 32 are connected to the hot-side heat source portion 110 of the thermoelectric generator 100, which will be described below. That is, while the thermostat 23 opens to a side of the radiator 21, a portion of the hot coolant (a coolant having a temperature between 90° C. and 100° C. in correspondence with “hot fluid” of the present invention) flowing through the radiator 21 is introduced via the hot coolant inflow pipe 31 and the hot coolant outflow pipe 32 to the hot-side heat source portion 110.

The thermoelectric generator 100 has a cold-side radiator 43 independent of the radiator 21, and a cold coolant inflow pipe 41 and a cold coolant outflow pipe 42 are connected to the cold-side radiator 43 and a cold-side heat source portion 120 of the thermoelectric generator 100, which will be described below. A water pump 44 is disposed on a way of the cold coolant outflow pipe 42. The water pump 44 operates so as to flow cold coolant in the cold-side radiator 43 (a coolant having a temperature between 30° C. and 40° C. in correspondence with “cold fluid” in the present invention) through the cold-side heat source portion 120.

As shown in FIGS. 2 and 3, the thermoelectric generator 100 is formed in such a manner that thermoelectric elements 130, which is conventional ones generating electric power by Seebeck effect, are disposed between the hot-side heat source portions 110 and the cold-side heat source portions 120 that are alternately stacked. In this embodiment, the thermoelectric generator 100 has a nine layer structure including two hot-side heat source portions 110, three cold-side heat source portions 120 and four thermoelectric elements 130. A thermal-conductivity grease coating or a heat transfer sheet is interposed between the hot-side heat source portion 110 and the thermoelectric element 130 and between the cold-side heat source portion 120 and the thermoelectric element 130.

A hot-side communicator 140 communicates a plurality of the hot-side heat source portions 110 in a stacking direction thereof. A cold-side communicator 150 communicates a plurality of the cold-side heat source portions 120 in a stacking direction thereof. The cold coolant flows out of the cold-side radiator 43 then flows through the plurality of the cold-side heat source portions 120. In the following, the stacking direction of the heat source portions 110, 120 will be referred to as an up-and-down direction as shown in FIG. 2.

As shown in FIGS. 4 and 5, the hot-side heat source portion 110 is a container having a flat rectangular shape and formed with a pair of plate members in such a manner of facing to each other. The hot-side heat source portion 110 has two projections 111 at one pair of opposing corners thereof (at a top-right and a lower-left portions in FIG. 4A) and a bolt hole 122 for inserting a bolt 181 at a center portion thereof. Inner fins 113 are disposed in the hot-side heat source portion 110 so as to transfer the heat of the hot coolant to the thermoelectric elements 130 effectively.

As shown in FIG. 5, a large-diameter pipe (corresponding to “one-side pipe” in the present invention) 141 and a small-diameter pipe (corresponding to “other-side” pipe in the present invention) 142 are connected to the projecting portions 111 in such a manner of communicating with an interior of the hot-side heat source portion 110. The small-diameter pipe 142 has a groove around an outer circumference of an upper end portion thereof. An O-ring (corresponding to “sealing member” in the present invention) 143 is attached on the groove.

An uppermost one of the hot-side heat source portions 110 has a hot coolant inlet pipe 144 and a hot coolant outlet pipe 145 (refer to FIGS. 4A and 4B) instead of the small-diameter pipe 142. A lowermost one of the hot-side heat source portions 110 has no large-diameter pipe 141 (not shown).

As shown in FIGS. 6 and 7, the cold-side heat source portion 120 is different from the above hot-side heat source portion 110 in a point of having two projections 121 at another pair of opposing corners (at lower-right and at upper-left portions in FIGS. 6A and 7A). The cold-side heat source portion 120 has substantially the same structure as that of the hot-side heat source portion 110 except for the above point. The cold-side heat source portion 120 has a bolt hole 122 at a center portion thereof and inner fins 113 therein for transferring the heat of the cold coolant to the thermoelectric elements 130 effectively.

As shown in FIG. 7, a large-diameter pipe 141 and a small-diameter pipe 142 on which the O-ring 143 is attached are connected to the projecting portions 121. An uppermost one of the cold-side heat source portions 120 has a cold coolant inlet pipe 151 and a cold coolant outlet pipe 152 (refer to FIGS. 6A and 6B) instead of the small-diameter pipe 142. A lowermost one of the cold-side heat source portions 120 has no large-diameter pipe 141 (not shown).

The thermoelectric generator 100 is assembled as follows. As shown in FIG. 8, the cold-side heat source portion 120, the thermoelectric element 130, the hot-side heat source portion 110 and the thermoelectric element 130 are repeatedly stacked in turn. The small-diameter pipe 142 of the lowermost one of the cold-side heat source portions 120 is inserted into the large-diameter pipe 141 of another one of the cold-side heat source portions 120 just above the lowermost one, interposing the O-ring 143 between the inner circumference of the large-diameter pipe 141 and the outer circumference of the small-diameter pipe 142. The large-diameter pipe 141, the small-diameter pipe 142 and the O-ring 143 constitute the cold-side communicator 150. The cold-side heat source portions 120 communicate with each other, and the cold coolant inlet pipe 151 and the cold coolant outlet pipe 152 open on the uppermost one of the cold-side heat source portions 120.

Similarly, the small-diameter pipe 142 of the lowermost one of the hot-side heat source portions 110 is inserted into the large-diameter pipe 141 of another one of the cold-side heat source portions 110 just above the lowermost one, interposing the O-ring 143 therebetween. The large-diameter pipe 141, the small-diameter pipe 142 and the O-ring 143 constitute the hot-side communicator 140. The hot-side heat source portions 110 communicate with each other, and the hot coolant inlet pipe 144 and the hot coolant outlet pipe 145 open on the uppermost one of the hot-side heat source portions 110.

Here, the hot-side communicators 140 and the cold-side communicators 150 are respectively disposed at one pair and another pair of diagonally opposing projections 111, 121 of the respective heat source portions 110, 120. Thus, the hot-side communicators 140 are not in contact with the cold-side heat source portions 120, and the cold-side communicators 150 are not in contact with the hot-side heat source portions 110.

A stack of the above hot-side heat source portions 110, the cold-side heat source portions 120 and the thermoelectric elements 130 is sandwiched between and supported by a lower plate 160 and an upper plate 170 (respectively having pipe holes at positions corresponding to the pipes 144, 145, 151 and 152). A plurality of bolts 181 and nuts 182 fastens the stack and the lower and upper plates 160, 170 applying a predetermined pressure in the upper-and-lower direction, so as to form the thermoelectric generator 100.

The hot coolant inlet pipe 144 of the thermoelectric generator 100 is connected to the hot coolant inflow pipe 31, and the hot coolant outlet pipe 145 is connected to the hot coolant outflow pipe 32. While, the cold coolant inlet pipe 151 is connected to the cold coolant inflow pipe 41, and the cold coolant outlet pipe 152 is connected to the cold coolant outflow pipe 42.

Next, the operation of the thermoelectric generator 100 having the above configuration will be described. When the thermostat 23 opens to the side of the radiator 21 by a temperature increase of the coolant (over 90° C. so as to be the hot coolant), a portion of the hot coolant flowing through the engine coolant circuit 20 flows through the hot coolant inflow pipe 31, the hot coolant inlet pipe 144 of the thermoelectric generator 100, the plurality of the hot-side heat source portions 110, the hot coolant outlet pipe 145 and the hot coolant outflow pipe 32, then returns to a point downstream of the radiator 21.

By the operation of the water pump 44, the cold coolant flows through the cold-side radiator 43, the cold coolant inflow pipe 41, the cold coolant intake pipe 151, the plurality of the cold-side heat source portions 120, the cold coolant outlet pipe 152, the cold coolant outflow pipe 42, then returns to the cold-side radiator 43.

Then, the thermoelectric elements 130 are exposed to a temperature difference by the hot coolant flowing through the hot-side heat source portion 110 and the cold coolant flowing through the cold-side heat source portion 120 so as to generate electric power, which is used for charging a battery (not shown) and for operating respective supplemental appliances.

When the thermoelectric elements 130 generates electric power, it is required that each of the hot-side heat source portion 110 and the cold-side heat source portion 120 is in contact with the thermoelectric element 130 at a given face pressure so as to reduce the contact thermal transmission resistance. In the present invention, by using the above-described respective communicators 140, 150 for connecting the respective heat source portions 110, 120, the communicators 140, 150 serve for a distance adjuster 140A that adjusts (smoothes) the dimension variation of the hot-side heat source portions 110, the cold-side heat source portions 120 and the thermoelectric devices 130 in the upper-and-lower direction. Thus, in the stack of hot-side heat source portions 110, the cold-side heat source portions 120 and the thermoelectric elements 130, the thermoelectric element 130 comes in well contact with each of the hot-side heat source portion 110 and the cold-side heat source portion 120 without excessive deformation. This serves to reduce an extra structure of the pressuring means disclosed in the prior art.

Further, it is possible to improve the assembling workability of the thermoelectric generator 100 by stacking the cold-side heat source portion 120, the thermoelectric element 130, the hot-side heat source portion 110 and the thermoelectric element 130 repeatedly in turn.

It is also possible to prevent a heat transmission between the hot-side heat source portion 110 and the cold-side heat source portion 120, by disposing the respective communicators 140, 150 at projections 111, 121 at one and another pairs of diagonally opposing corners, not to bring the hot-side heat source portions 110 and the cold-side communicators 150 with each other and the cold-side heat source portions an the hot-side communicators 140 with each other. That is, the amount of electric power generation by the thermoelectric elements 130 is secured by keeping the temperature difference between the both heat source portions 110, 120.

Furthermore, by using the coolant (hot coolant) of the engine 10 for the heat source of the hot-side heat source portions 110, the thermoelectric generator 100 can use the exhaust heat of the engine 10 effectively.

### Second Embodiment

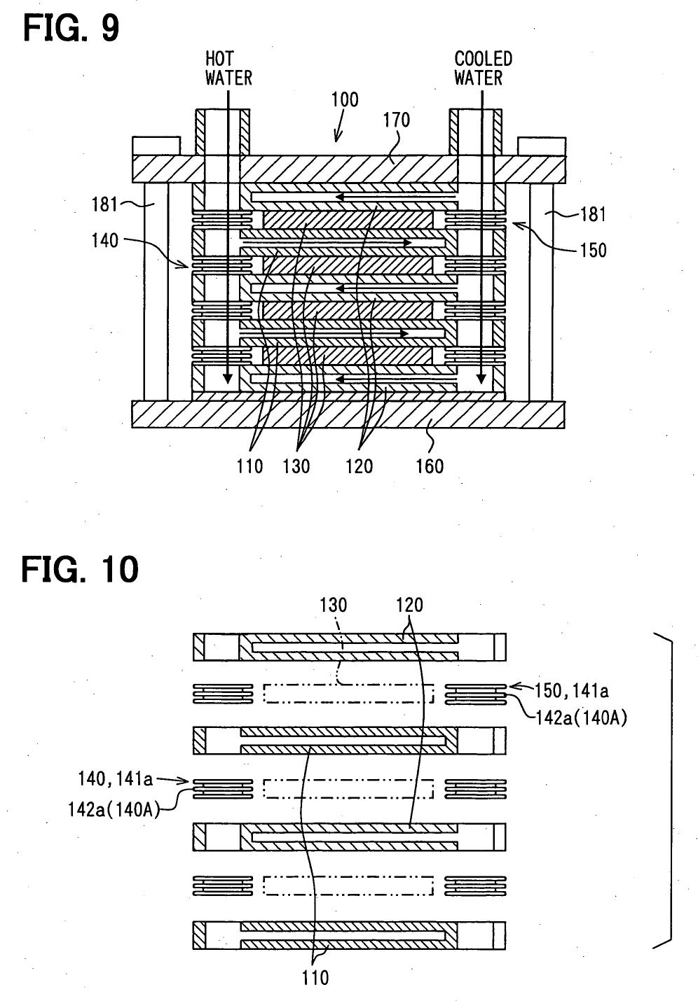

A second embodiment of the present invention is shown in FIGS. 9 and 10. The second embodiment has a different configuration from that of the above first embodiment in the respective communicators 140, 150. The second embodiment adopts pipes 141a (corresponding to “pipe” in the present invention) having bellows 142a, which extends and shrinks according to a distance between the both ends of the pipe 141a. The bellows 142a serves as the distance adjuster 140A.

As shown in FIG. 10, a stack of the heat source portions 110, 120 is formed by alternately stacking the cold-side heat source portions 120 and the hot-side heat source portions 110, disposing the pipes 141a between the respective heat source portions 110, 120 and blazing them integrally. In the stack, the clearances between both of the heat source portions 110, 120 are set to be larger than a thickness of the thermoelectric device 130.

Here, the hot-side heat source portions 140 (at left side in FIG. 10) pass the hot coolant over the cold-side heat source portions 120 disposed between the hot-side heat source portions 110. In a same manner, the cold-side heat source portions 150 (at right side in FIG. 10) pass the cold coolant over the hot-side heat source portions 110 disposed between the cold-side heat source portions 120.

Then, the thermoelectric elements 130 are inserted into clearances in the blazed stack. The stack of the heat source portions 110, 120 and the thermoelectric elements 130 are sandwiched between and supported by a lower plate 160 and an upper plate 170, then the stake and the upper and the lower plates 160, 170 are fastened by a plurality of bolts 181.

In this embodiment, by using the pipe 141a provided with the bellows 142a for forming the respective communicators 140, 150, intervals between the respective heat source portions 110, 120 are adjusted by the shrinkage of the bellows 142a (the distance adjusters 140A) when fastening the stack with the bolts 181. Thus, it is possible to bring the thermoelectric elements 130 in well contact with the respective heat source portions 110, 120 without excessive deformation.

In this second embodiment, the respective pipes 141a are in contact with the hot-side heat source portions 110 and the cold-side heat source portions 120 in contrast to the first embodiment, causing a small amount of thermal transfer between the hot coolant and the cold coolant. However, the second embodiment does not require the O-ring 143, and the two kinds of the large-diameter pipe 141 and the small-diameter pipe 142 in the first embodiment is unified into one kind of pipe 141a, so as to reduce the kind of the components.

### Third Embodiment

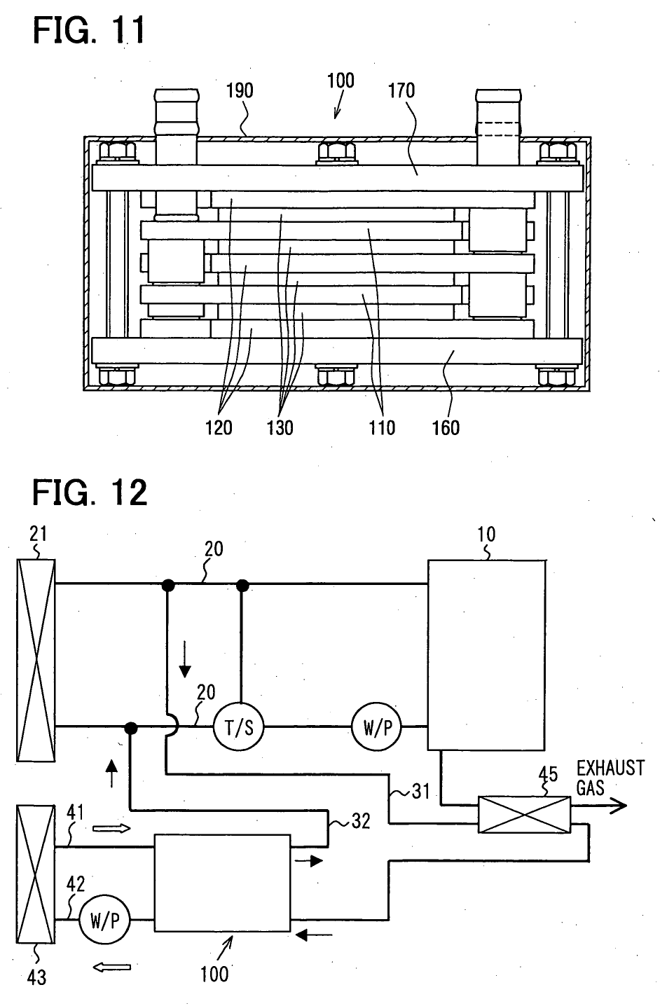

A third embodiment of the present invention is shown in FIG. 11. The third embodiment, in contrast to the first embodiment, a stack of the hot-side heat source portions 110, the cold-side heat source portions 120 and the thermoelectric elements 130 sandwiched between the lower plate 160 and the upper plate 170 is enclosed by a vacuum container 190 that keeps an internal space thereof to an approximately vacuum state.

A heat transfer is reduced in a vacuum compared to that in the air, so as to reduce the temperature difference between the both heat source portions 110, 120 caused by the thermal dissipation from the hot-side heat source portions 110 to the outside and by the thermal absorption by the cold-side heat source portions 120.

When the vacuum container 190 is not adopted and the cold-side heat source portions 120 are colder than the outer air, the water vapor in the air is condensed on the surface of the cold-side heat source portions 120, which may cause a short circuit or corrosion in the thermoelectric elements 130. In the third embodiment, this issue does not occur.

### Other Embodiments

In contrast to the above first to third embodiments, as shown in FIG. 12, the thermoelectric generator 100 may have a heater 45 that exchanges heat between an exhaust gas of the engine 10 and the hot coolant, so as to increase the temperature difference between the cold coolant and the hot coolant. Thus, by using the heat of the exhaust gas effectively, the electric power generation at the thermoelectric elements 130 increases. Further, the exhaust gas 10 of the engine 100 may be introduced through the hot-side heat source portions 110, though the drawing is not shown.

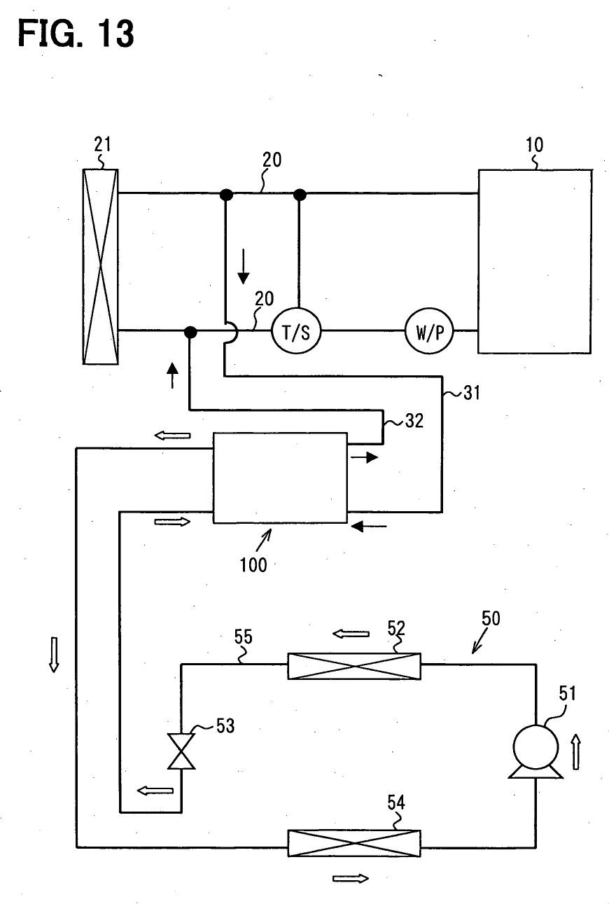

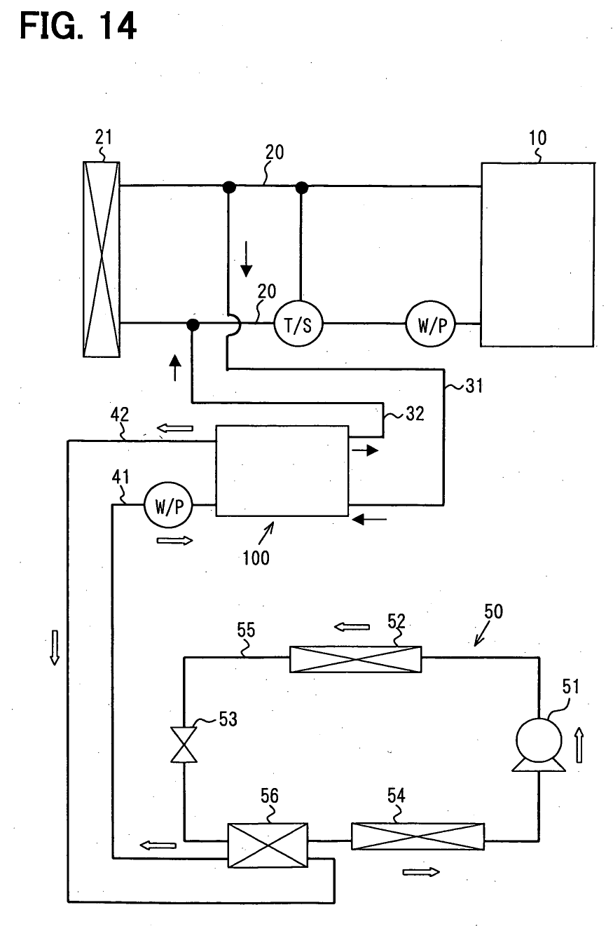

As the cold fluid in the cold-side heat source portions 120, the refrigerant circulating in the vehicular refrigerating cycle apparatus 50 may be used. The refrigerating cycle apparatus 50, as conventionally known, has a closed circuit having a compressor 51, a condenser 52, an expansion valve 53 and the evaporator 54 connected in turn by a coolant pipe 55. Then, as shown in FIG. 13, the cold-side heat source portion 120 is supplied with a refrigerant in the refrigerating cycle apparatus 50 (after decompressed by the expansion valve 53), instead of the cold coolant. Alternately, as shown in FIG. 14, by comprising a cooler 56 between the expansion valve 53 and the evaporator 54, the refrigerant further cools the cold coolant (fluid). Thus, the cold-side heat source portion 120 becomes colder than the conventional refrigerant or coolant for the air conditioner or for the engine 10.

This description of the invention is merely exemplary in nature and, thus, variations that do not depart from the gist of the invention are intended to be within the scope of the invention. Such variations are not to be regarded as a departure from the spirit and scope of the invention.

1. A thermoelectric generator comprising:
a plurality of hot-side heat source portions in which hot fluid flows;
a plurality of cold-side heat source portions in which cold fluid colder than the hot fluid flows and alternately stacked together with the plurality of hot-side heat source portions;
a thermoelectric element interposed between the hot-side heat source portion and the cold-side heat source portion;
a hot-side communicator communicating the plurality of hot-side heat source portions; and
a cold-side communicator communicating the plurality of cold-side heat source portions,
wherein each of the hot-side communicator and the cold-side communicator has a distance adjuster for adjusting distances between the hot-side heat source portions and the cold-side heat source portions so as to bring them in contact with the thermoelectric elements in the stacking direction thereof.

2. The thermoelectric generator according to claim 1, wherein each of the communicators has:
a one-side pipe located on one side of each of the heat source portions and connected by a sealing member;
another-side pipe located on the other side of each of the heat source portions and inserted into the one-side pipe so as to implement the distance adjuster; and
a sealing member disposed between an inner circumference of the one-side pipe and an outer circumference of the other-side pipe.

3. The thermoelectric generator according to claim 1, wherein each of the communicators has:
a pipe disposed between the heat source portions; and
a bellows disposed at longitudinal end of the pipe and extendible and shrinkable in a longitudinal direction of the pipe so as to implement the distance adjuster.

4. The thermoelectric generator according to claim 1, wherein:
the hot-side communicator is disposed not to be in contact with the cold-side heat source portions; and
the cold-side communicator is disposed not to be in contact with the hot-side heat source portions.

5. The thermoelectric generator according to claim 1, further comprising:
a vacuum container for keeping an internal space thereof vacuum and enclosing the heat source portions, the thermoelectric elements and the communicators.
